(19) United States
(12) Patent Application Publication
(10) Pub. No.: US 2026/0110080 A1
(43) Pub. Date: Apr. 23, 2026

(54) METHOD OF DEPOSITING FILM

(71) Applicant: Tokyo Electron Limited, Tokyo (JP)

(72) Inventors: Yutaka MOTOYAMA, Boise, ID (US); Hiroto FUJIKAWA, Yamanashi (JP); Tuhin Shuvra Basu, Albany, NY (US)

(21) Appl. No.: 19/351,692

(22) Filed: Oct. 7, 2025

(30) Foreign Application Priority Data
Oct. 21, 2024 (JP) 2024-185399

(51) Int. Cl. C23C 16/04; C23C 16/28; C23C 16/40; C23C 16/56

(52) U.S. Cl. CPC C23C 16/045; C23C 16/28; C23C 16/401; C23C 16/56

(57) ABSTRACT

A method of depositing film, the method includes preparing a substrate on which a plurality of recesses each having an opening with a different width are formed, depositing a silicon-containing film along surfaces of the plurality of recesses, filling the plurality of recesses on which the silicon-containing film is deposited with a carbon-containing film, exposing the silicon-containing film deposited on upper portions of the plurality of recesses from the carbon-containing film by anisotropically etching the carbon-containing film in a thickness direction of the substrate, and removing the silicon-containing film exposed from the carbon-containing film by etching the silicon-containing film using the carbon-containing film as an etching mask.

### CROSS-REFERENCE TO RELATED APPLICATIONS

The present application is based on and claims priority to Japanese patent application no. 2024-185399 filed on Oct. 21, 2024, with the Japan Patent Office, the entire contents of which are hereby incorporated by reference.

### BACKGROUND OF THE INVENTION

### 1. Field of the Invention

The disclosures herein relate to methods of depositing films.

### 2. Description of the Related Art

Patent Literature (PTL) 1 discloses a technology for bottom-up growth of a silicon film from a bottom surface of a recess toward an opening. In PTL 1, the silicon film is deposited on the entirety within the recess, the silicon film on an upper portion of an inner wall of the recess is removed while the silicon film on the bottom surface of the recess remains by etching using a chlorine gas, and then the silicon film is selectively deposited on the silicon film remaining on the bottom surface of the recess.

### CITATION LIST

### Patent Literature

[PTL 1] Japanese Laid-open Patent Application Laid-open no. 2019-197872

### SUMMARY OF THE INVENTION

A method of depositing a film, the method includes preparing a substrate on which a plurality of recesses each having an opening with a different width are formed, depositing a silicon-containing film along surfaces of the plurality of recesses, filling the plurality of recesses on which the silicon-containing film is deposited with a carbon-containing film, exposing the silicon-containing film deposited on upper portions of the plurality of recesses from the carbon-containing film by anisotropically etching the carbon-containing film in a thickness direction of the substrate, and removing the silicon-containing film exposed from the carbon-containing film by etching the silicon-containing film using the carbon-containing film as an etching mask.

### BRIEF DESCRIPTION OF THE DRAWINGS

FIG. 1 is a flowchart illustrating a method of depositing a film according to an embodiment;

FIG. 2 is a cross-sectional view (1) illustrating the method of depositing the film according to the embodiment;

FIG. 3 is a cross-sectional view (2) illustrating the method of depositing the film according to the embodiment;

FIG. 4 is a cross-sectional view (3) illustrating the method of depositing the film according to the embodiment;

FIG. 5 is a cross-sectional view (4) illustrating the method of depositing the film according to the embodiment;

FIG. 6 is a cross-sectional view (5) illustrating the method of depositing the film according to the embodiment;

FIG. 7 is a cross-sectional view (6) illustrating the method of depositing the film according to the embodiment; and

FIG. 8 is a cross-sectional view (7) illustrating the method of depositing the film according to the embodiment.

### DESCRIPTION OF THE PREFERRED EMBODIMENTS

In the following, embodiments of the present invention will be described with reference to the accompanying drawings. In the drawings, the same or corresponding constituent elements are denoted with the same reference numerals, and redundant descriptions will be omitted.

### [Method of Depositing Film]

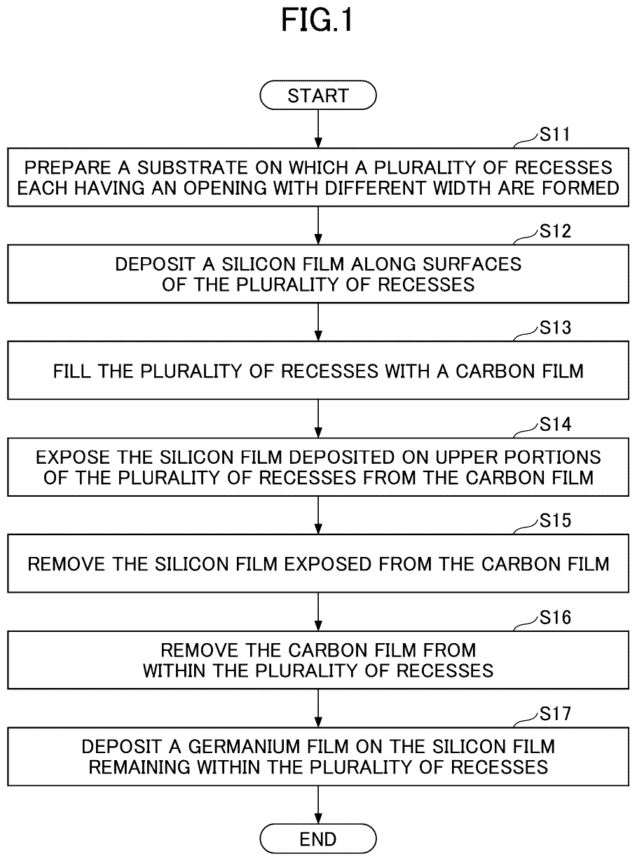

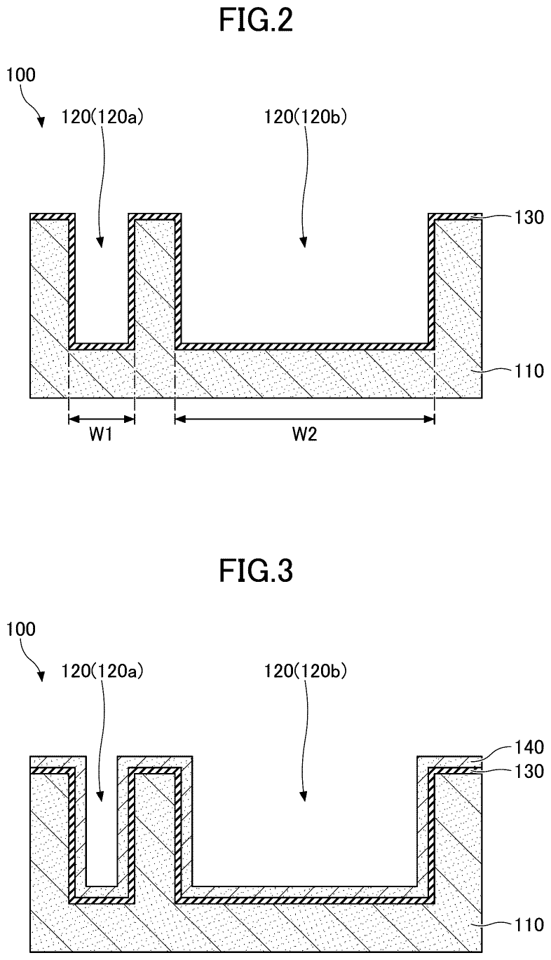

A method of depositing a film according to the embodiment will be described with reference to FIGS. 1 to 8. FIG. 1 is a flowchart illustrating the method of depositing the film according to the embodiment. FIGS. 2 to 8 are cross-sectional views illustrating the method of depositing the film according to the embodiment. The method of depositing the film according to the embodiment includes steps S11 to S17 shown in FIG. 1.

In the step S11, as shown in FIG. 2, a substrate 100 is prepared. The substrate 100 has a silicon substrate 110. A plurality of recesses 120 each having an opening with a different width are provided on a surface of the silicon substrate 110. In the example of FIG. 2, a recess 120a having a first opening width W1 and a recess 120b having a second opening width W2 are provided on the surface of the silicon substrate 110. The second opening width W2 is wider than the first opening width W1. The recesses 120a and 120b are, for example, trenches. In the present disclosure, the recesses 120a and 120b are collectively referred to as recesses 120. A silicon oxide film 130 is provided on the surface of the recesses 120. The silicon oxide film 130 is an example of an insulating film.

In the step S12, as shown in FIG. 3, a silicon film 140 is deposited along surfaces of the plurality of recesses 120. In the step S12, the silicon film 140 may be deposited so as to cover the surface of the silicon oxide film 130. In the step S12, the silicon film 140 may be deposited so that openings of the plurality of recesses 120 are not blocked. The silicon film 140 is amorphous. The silicon film 140 is non-doped. For example, the silicon film 140 can be deposited with chemical vapor deposition (CVD) using a silicon source gas. The silicon film 140 is an example of a silicon-containing film.

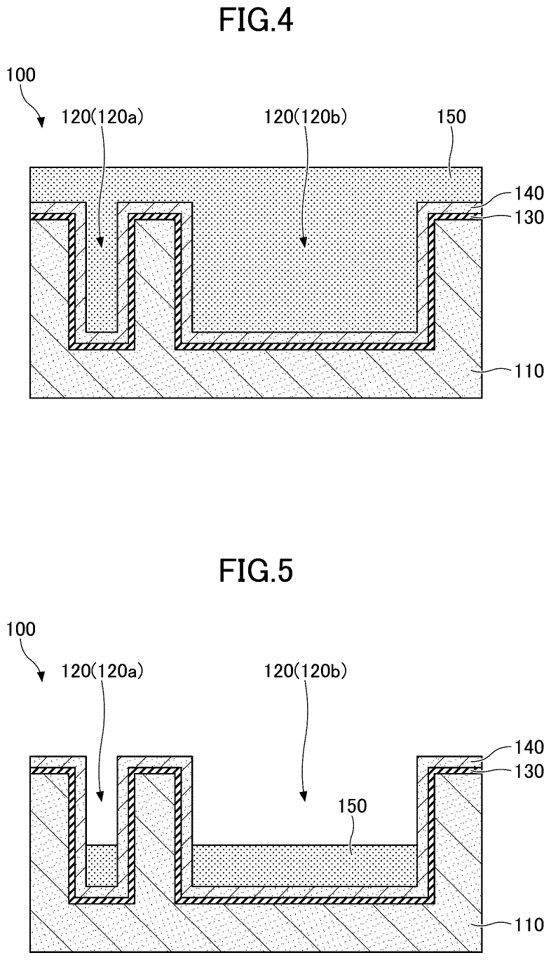

In the step S13, as shown in FIG. 4, the plurality of recesses 120 are filled with a carbon film 150. In the step S13, the carbon film 150 may be deposited so as to cover the entirety of the silicon film 140 deposited along the surfaces of the recesses 120. In the step S13, the carbon film 150 may be deposited so as to completely fill the recesses 120. For example, the carbon film 150 is a spin-on carbon film. In this case, it is easy to fill the recesses 120 with the carbon film 150. The carbon film 150 is an example of a carbon-containing film.

In the step S14, as shown in FIG. 5, the silicon film 140 deposited on upper portions of the plurality of recesses 120 is exposed from the carbon film 150 by anisotropically etching the carbon film 150 in the thickness direction of the substrate 100. In the step S14, the silicon film 140 deposited on the upper surfaces and the upper portions of lateral surfaces of the recesses 120 may be exposed from the carbon film 150 without exposing the silicon film 140 deposited on bottom surfaces and lower portions of the lateral surfaces of the recesses 120 from the carbon film 150. For example, by supplying oxygen plasma to the substrate 100, the silicon film 140 deposited on the upper portions of the recesses 120 can be exposed from the carbon film 150. When oxygen plasma is used, the carbon film 150 deposited on the upper surfaces and the lateral surfaces of the recesses 120 can be easily removed without removing the carbon film 150 deposited on the bottom surfaces of the recesses 120. However, by supplying hydrogen plasma to the substrate 100, the silicon film 140 deposited above the plurality of recesses 120 may be exposed from the carbon film 150.

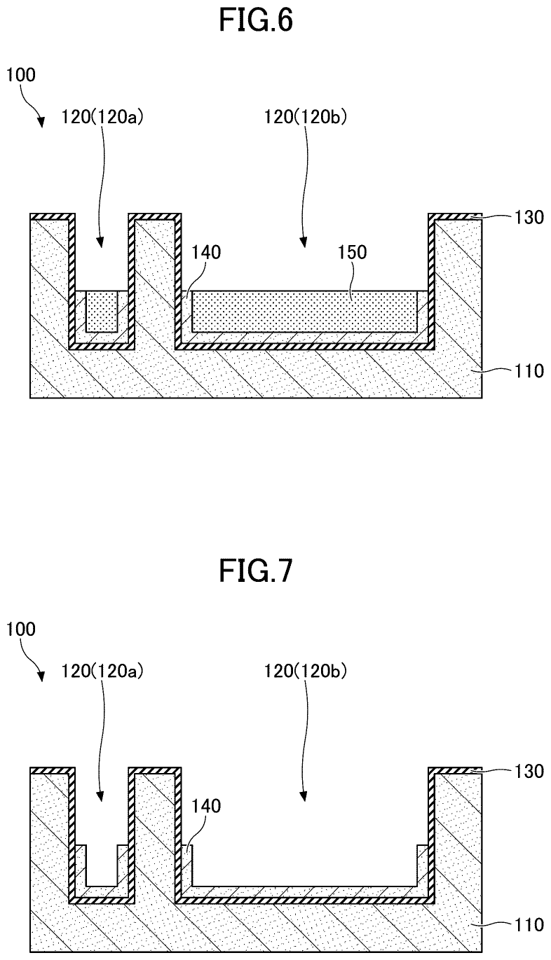

In step S15, as shown in FIG. 6, the silicon film 140 exposed from the carbon film 150 is removed by etching the silicon film 140 using the carbon film 150 as an etching mask. For example, the silicon film 140 exposed from the carbon film 150 can be removed by supplying a fluorine-containing gas to the silicon film 140. When the silicon film 140 is removed, the substrate 100 may be maintained at a temperature of 150° C. or less. In this case, the carbon film 150 is not sublimated.

In step S16, as shown in FIG. 7, the carbon film 150 is removed from the plurality of recesses 120. In step S16, the carbon film 150 is selectively removed so that the silicon film 140 is not removed. Thus, the silicon film 140 remains selectively on the bottom surfaces of the plurality of recesses 120 having different opening widths. That is, the silicon film 140 can be selectively deposited on the bottom surfaces of each of the plurality of recesses 120 having different opening widths. For example, by supplying oxygen plasma to the carbon film 150, the carbon film 150 can be selectively removed with respect to the silicon film 140.

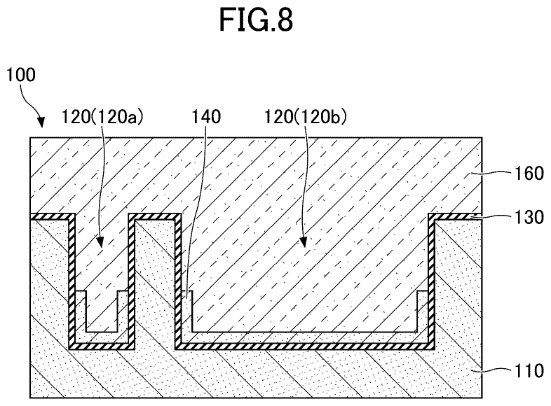

In the step S17, as shown in FIG. 8, the plurality of recesses 120 from within which the carbon film 150 has been removed are filled with a germanium film 160. In the step S17, the plurality of recesses 120 may be filled with the germanium film 160 with chemical vapor deposition using a germanium-containing gas. In the chemical vapor deposition using the germanium-containing gas, the germanium film 160 is not or hardly deposited on the surface of the silicon oxide film 130, while the germanium film 160 is deposited on the surface of the silicon film 140. Therefore, the germanium film 160 is selectively deposited on the surface of the silicon film 140 with respect to the surface of the silicon oxide film 130. As a result, the germanium film 160 can be bottom-up grown from the bottom surfaces of the recesses 120 toward the openings. The germanium film 160 is amorphous. The germanium film 160 is non-doped. The germanium film 160 is an example of a germanium-containing film.

As described above, according to the method of depositing the film according to the embodiment, first, in the step S12, the silicon film 140 is deposited along the surfaces of the plurality of recesses 120 each having an opening with a different width. Next, in the step S13, the plurality of recesses 120 on which the silicon film 140 is deposited is filled with the carbon film 150. Next, in the step S14, the silicon film 140 deposited on the upper portions of the plurality of recesses 120 are exposed from the carbon film 150 by anisotropically etching the carbon film 150 in the thickness direction of the substrate 100. Next, in step S15, the silicon film 140 is exposed from the carbon film 150 by etching the silicon film 140 using the carbon film 150 as an etching mask. In this case, the silicon film 140 selectively remains on the bottom surface of each of the plurality of recesses 120. That is, the silicon film 140 can be selectively deposited on the bottom surface of each of the plurality of recesses 120 having different opening widths. As a result, the germanium film 160 can be bottom-up grown from the bottom surface of the recesses 120 toward the opening.

Conversely, there is a method of depositing a silicon film on the entirety in the recess, removing the silicon film on the upper part of the inner wall of the recess while leaving the silicon film on the bottom surface of the recess by etching using a chlorine gas, and then selectively depositing the silicon film on the silicon film remaining on the bottom surface of the recess. When using this method to form the silicon film in the plurality of recesses having different opening widths, it is difficult to leave the silicon film having the same or substantially the same thickness on the bottom surfaces of the plurality of recesses each having an opening with a different width. Therefore, when the recesses are subsequently filled with germanium film 160, it is difficult to perform bottom-up growth of the germanium film 160.

### [Types of Gases]

Specific examples of gases used in the film formation method according to the embodiment will be described.

As the silicon source gas used for depositing the silicon film 140, any gas that is applicable to chemical vapor deposition is sufficient, and for example, one or a plurality of hydrogenated silane gases, halogen-containing silicon gases, and aminosilane gases can be used in combination. Examples of hydrogenated silane gases include SiH₄, Si₂H₆, and Si₃H₈. Examples of halogen-containing silicon gases include fluorine-containing silicon gases such as SiF₄, SiHF₃, SiH₂F₂, and SiH₃F, chlorine-containing silicon gases such as SiCl₄, SiHCl₃, SiH₂Cl₂, and SiH₃Cl, and bromine-containing gases such as SiBr₄, SiHBr₃, SiH₂Br₂, and SiH₃Br. Examples of aminosilane-based gases include DIPAS (diisopropylaminosilane), 3DMAS (tris(dimethylamino)silane), and BTBAS (bis(tertialbutylamino)silane).

As the fluorine-containing gas used for removing the silicon film 140, for example, a mixed gas of fluorine gas and nitrogen gas can be used.

As the germanium source gas used for depositing the germanium film 160, as long as it is applicable to chemical vapor deposition, for example, a hydrogenated germanium gas, a halogen-containing germanium gas, and an aminogermane-based gas can be used. Examples of the hydrogenated germanium gas include GeH₄, Ge₂H₆, and Ge₃H₈. Examples of the halogen-containing germanium gas include fluorine-containing germanium gas such as GeF₄, GeHF₃, GeH₂F₂, and GeH₃F, chlorine-containing germanium gas such as GeCl₄, GeHCl₃, GeH Cl₂, and GeH₃Cl, and bromine-containing gas such as GeBr₄, GeHBr₃, GeH Br₂, and GeH₃Br. Examples of the aminogermane-based gas include DMAG (dimethylaminogermane), DEAG (diethylaminogermane), BDMAG (bis(dimethylamino)germane), BDEAG (bis(diethylamino)germane), and 3DMAG (tris(dimethylamino)germane).

Further, the present invention is not limited to these embodiments, and various variations and modifications may be made without departing from the scope of the present invention.

In the above embodiments, a case where the insulating film is the silicon oxide film 130 has been described, but the present disclosure is not limited to the above. The insulating film may be a silicon nitride film or a high permittivity (high-k) film.

In the above embodiment, a case where the silicon-containing film is the non-doped amorphous silicon film 140 has been described, but the present disclosure is not limited to the above. The silicon-containing film may be any film on which a germanium-containing film can be deposited. For example, the silicon-containing film may contain a p-type impurity such as boron (B) or an n-type impurity such as phosphorus (P). For example, the silicon-containing film may contain carbon (C). For example, the silicon-containing film may contain germanium (Ge).

In the above embodiments, the carbon-containing film is a carbon film 150, but the present disclosure is not limited to the above. For example, the carbon-containing film may contain nitrogen (N).

In the above embodiments, the germanium-containing film is a germanium film 160, but the present disclosure is not limited to the above. For example, the germanium film may be a silicon germanium film.

According to the present disclosure, a technology for selectively depositing a silicon-containing film on the bottom surface of each of a plurality of recesses having different opening widths is provided.

What is claimed is:

1. A method of depositing a film, the method comprising:
preparing a substrate on which a plurality of recesses each having an opening with a different width are formed;
depositing a silicon-containing film along surfaces of the plurality of recesses;
filling the plurality of recesses on which the silicon-containing film is deposited with a carbon-containing film;
exposing the silicon-containing film deposited on upper portions of the plurality of recesses from the carbon-containing film by anisotropically etching the carbon-containing film in a thickness direction of the substrate; and
removing the silicon-containing film exposed from the carbon-containing film by etching the silicon-containing film using the carbon-containing film as an etching mask.

2. The method of depositing the film according to claim 1, wherein the filling with the carbon-containing film includes depositing the carbon-containing film so as to cover an entirety of the silicon-containing film deposited along the surfaces of the plurality of recesses.

3. The method of depositing the film according to claim 1, wherein the filling with the carbon-containing film includes completely filling the plurality of recesses with the carbon-containing film.

4. The method of depositing the film according to claim 1, wherein the exposing from the carbon-containing film includes supplying oxygen plasma to the carbon-containing film.

5. The method of depositing the film according to claim 1, wherein the removing the silicon-containing film includes supplying a fluorine-containing gas to the silicon-containing film.

6. The method of depositing the film according to claim 1, the method further comprising:
removing the carbon-containing film from within the plurality of recesses from which the silicon-containing film has been removed; and
depositing a germanium-containing film on the silicon-containing film remaining within the plurality of recesses by supplying a germanium-containing gas to within the plurality of recesses from which the carbon-containing film has been removed.

7. The method of depositing the film according to claim 1, wherein the silicon-containing film is an amorphous silicon film.

8. The method of depositing the film according to claim 1, wherein the carbon-containing film is a spin-on carbon film.
